(19) United States
(12) Patent Application Publication
(10) Pub. No.: US 2025/0079271 A1
(43) Pub. Date: Mar. 6, 2025

(54) SEMICONDUCTOR DEVICE, POWER CONVERTER, AND METHOD OF MANUFACTURING SEMICONDUCTOR DEVICE

(71) Applicant: Mitsubishi Electric Corporation, Tokyo (JP)

(72) Inventors: Naoki YOSHIMATSU, Tokyo (JP); Norikazu SAKAI, Tokyo (JP); Hideo KOMO, Tokyo (JP)

(73) Assignee: Mitsubishi Electric Corporation, Tokyo (JP)

(21) Appl. No.: 18/726,273

(22) PCT Filed: Mar. 17, 2022
(86) PCT No.: PCT/JP2022/012383

§ 371 Date: Jul. 2, 2024

(51) Int. Cl. H01L 23/495; H01L 23/29; H01L 23/31; H01L 29/16

(52) U.S. Cl. CPC H01L 23/49548; H01L 23/293; H01L 23/3192; H01L 23/49582; H10D 62/8325

(57) ABSTRACT

A semiconductor device includes: a semiconductor substrate having a semiconductor element formed thereon; a surface electrode formed on a surface of the semiconductor substrate; a protective film having an opening from which a portion of the surface electrode is exposed; a plated electrode formed on the portion of the surface electrode exposed from the opening of the protective film; and a lead frame connected to the plated electrode via a bonding material. The bonding material covers a portion of the protective film at an edge of the opening, and a width of the portion of the protective film at the edge of the opening covered with the bonding material is greater than a thickness of a portion of the bonding material between the lead frame and the plated electrode.

### TECHNICAL FIELD

The present disclosure relates to semiconductor devices, power converters, and methods of manufacturing the semiconductor devices.

### BACKGROUND ART

A semiconductor device having a structure in which a metal lead frame is connected to a surface electrode formed on a surface of a semiconductor substrate is known. For example, Patent Document 1 shown below discloses a semiconductor device having a configuration in which a plated electrode is formed on a portion of a surface electrode exposed from a protective film and the plated electrode and a lead frame are connected via solder as a bonding material. In Patent Document 1, solder connecting the plated electrode and the lead frame is in contact with a sloped side surface of the protective film. The protective film, the plated electrode, the solder, and the lead frame described above are sealed by a molding resin.

### PRIOR ART DOCUMENTS

### Patent Document

Patent Document 1: Japanese Patent Application Laid-Open No. 2013-16538

### SUMMARY

### Problem to be Solved by the Invention

In the semiconductor device having a configuration as described above, when heat generation and cooling associated with turning on and off of a semiconductor element result in a temperature distribution, stress is generated at a boundary between members due to a difference in coefficient of linear expansion between the members. In particular, when the amount of expansion and contraction of a molding resin and a protective film and the amount of expansion and contraction of a plated electrode, a bonding material, and a lead frame differ from each other, and stress is repeatedly generated at a boundary between them, an end of the plated electrode having a low peel strength might be peeled to cause breakdown of the semiconductor device.

The present disclosure has been conceived to solve a problem as described above, and it is an object of the present disclosure to prevent peeling of a plated electrode due to stress attributable to a difference in coefficient of linear expansion between parts of a semiconductor device.

### Means to Solve the Problem

A semiconductor device according to the present disclosure includes: a semiconductor substrate having a semiconductor element formed thereon; a surface electrode formed on a surface of the semiconductor substrate; a protective film formed on the surface electrode and having an opening from which a portion of the surface electrode is exposed; a plated electrode formed on the portion of the surface electrode exposed from the opening of the protective film; a lead frame connected to the plated electrode via a bonding material; a molding resin to seal the semiconductor substrate, the surface electrode, the protective film, the plated electrode, and the lead frame, wherein the bonding material covers a portion of the protective film at an edge of the opening, and a width of the portion of the protective film at the edge of the opening covered with the bonding material is greater than a thickness of a portion of the bonding material between the lead frame and the plated electrode.

### Effects of the Invention

According to the present disclosure, peeling of the plated electrode due to stress attributable to a difference in coefficient of linear expansion between parts of the semiconductor device can be prevented.

These and other objects, features, aspects and advantages of the present disclosure will become more apparent from the following detailed description when taken in conjunction with the accompanying drawings.

### BRIEF DESCRIPTION OF DRAWINGS

FIG. 1 is a cross-sectional view illustrating a configuration of a main portion of a semiconductor device according to Embodiment 1.

FIG. 2 is a diagram for explaining a method of manufacturing the semiconductor device according to Embodiment 1.

FIG. 3 is a diagram for explaining the method of manufacturing the semiconductor device according to Embodiment 1.

FIG. 4 is a diagram for explaining the method of manufacturing the semiconductor device according to Embodiment 1.

FIG. 5 is a diagram for explaining the method of manufacturing the semiconductor device according to Embodiment 1.

FIG. 6 is a diagram for explaining the method of manufacturing the semiconductor device according to Embodiment 1.

FIG. 7 is a diagram for explaining the method of manufacturing the semiconductor device according to Embodiment 1.

FIG. 8 is a cross-sectional view illustrating a configuration of a main portion of a semiconductor device according to Embodiment 2.

FIG. 9 is a cross-sectional view illustrating a configuration of a main portion of a semiconductor device according to Embodiment 3.

FIG. 10 is a diagram showing a configuration of a power conversion system to which a power converter according to Embodiment 4 has been applied.

### DESCRIPTION OF EMBODIMENTS

### Embodiment 1

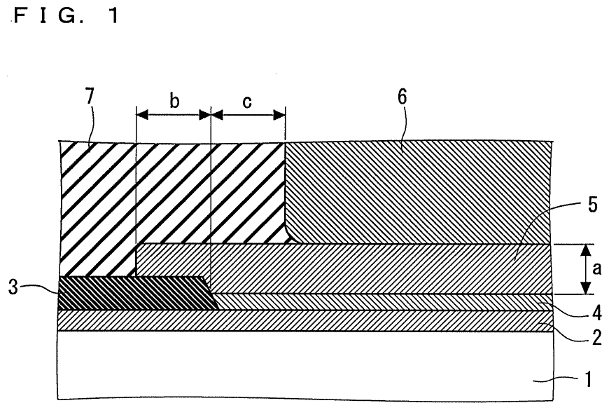

FIG. 1 is a cross-sectional view illustrating a configuration of a main portion (specifically, a portion near a position where a semiconductor element and a lead frame are connected) of a semiconductor device according to Embodiment 1. As illustrated in FIG. 1, the semiconductor device according to Embodiment 1 includes a semiconductor substrate 1 having a semiconductor element formed thereon and a surface electrode 2 formed on a surface of the semiconductor substrate 1. The semiconductor element formed on the semiconductor substrate 1 is not particularly limited and may be any semiconductor element, such as a MOSFET, an IGBT, a Schottky barrier diode, and a PN junction diode, for example.

A protective film 3 having an opening from which a portion of the surface electrode 2 is exposed is formed on the surface electrode 2, and a plated electrode 4 is formed on the portion of the surface electrode 2 exposed from the opening of the protective film 3. In the present embodiment, the protective film 3 is formed to cover an outer edge portion of the surface electrode 2, and a central portion of the surface electrode 2 is exposed from the opening of the protective film 3. The plated electrode 4 is thus formed on the central portion of the surface electrode 2.

The plated electrode 4 is formed by plating the portion of the surface electrode 2 exposed from the opening of the protective film 3 with nickel and the like, for example. The protective film 3 is preferably formed of a low modulus, chemically stable, high heat resistance resin material, such as polyimide, in terms of assembly and reliability.

The plated electrode 4 is connected to a lead frame 6 via a bonding material 5. The lead frame 6 is formed of copper or a copper alloy, for example. The semiconductor substrate 1, the surface electrode 2, the protective film 3, the plated electrode 4, and the lead frame 6 are sealed by a molding resin 7.

A portion of the bonding material 5 protrudes from above the plated electrode 4 and covers an edge of the opening of the protective film 3. A boundary portion between the plated electrode 4 having a low peel strength and the protective film 3 is thereby covered with the bonding material 5 to prevent peeling of the plated electrode 4.

A width of a portion of the protective film 3 at the edge of the opening covered with the bonding material 5 is preferably greater than a thickness of a portion of the bonding material 5 below the lead frame 6, that is, a thickness of a portion of the bonding material 5 between the lead frame 6 and the plated electrode 4. That is to say, as illustrated in FIG. 1, a relationship b>a preferably holds, where a is the thickness of the portion of the bonding material 5 between the lead frame 6 and the plated electrode 4, b is the width of the portion of the protective film 3 at the edge of the opening covered with the bonding material 5.

Furthermore, an end surface of the lead frame 6 covered with the molding resin 7 is at a position offset from a position above an end of the plated electrode 4, that is, a position above the boundary portion between the plated electrode 4 and the protective film 3. In Embodiment 1, the end surface of the lead frame 6 covered with the molding resin 7 is located above the plated electrode 4. This suppresses application of stress generated at a boundary portion between the lead frame 6 and the molding resin 7 to the end of the plated electrode 4 having a low peel strength to further suppress peeling of the plated electrode 4.

The amount of offset of a position of the end surface of the lead frame 6 covered with the molding resin 7 from a position of the end of the plated electrode 4 is preferably greater than the thickness of the portion of the bonding material 5 between the lead frame 6 and the plated electrode 4. That is to say, as illustrated in FIG. 1, a relationship c>a preferably holds, where c is the amount of offset of the position of the end surface of the lead frame 6 covered with the molding resin 7 from the position of the end of the plated electrode 4.

The bonding material 5 is applied not only to the plated electrode 4 but also to the protective film 3 formed of resin and is required to cover the protective film 3 after bonding the lead frame 6. The bonding material 5 is thus preferably not a material with wetting, such as solder, but a material curing as it is at an application position, such as sintered silver as a sintered body of silver and a conductive adhesive.

The bonding material 5 formed of sintered silver can be formed by applying and sintering a nanosilver paste. While a method of sintering nanosilver includes pressure sintering by heating with application of pressure and pressureless sintering by heating without application of pressure, pressureless sintering is preferable in the present embodiment considering that the bonding material 5 has a portion on which the lead frame 6 is not present and the bonding material 5 is porosified to be low modulus.

To suppress stress generated in the semiconductor device, materials having close coefficients of linear expansion are generally selected as materials for adjacent members in design of the semiconductor device. For example, the molding resin 7 and the lead frame 6 are caused to have close coefficients of linear expansion, so that a difference in amount of expansion and contraction between the molding resin 7 and the lead frame 6 associated with a change in environmental temperature, such as a heating and cooling cycle, can be reduced.

When the semiconductor element is on, however, a majority of heat generated in the semiconductor element is dissipated toward a lower surface of the semiconductor substrate 1, but the plated electrode 4, the bonding material 5, and the lead frame 6 formed of a metal material having a high thermal conductivity have higher temperatures than the protective film 3 and the molding resin 7 formed of a resin material having a low thermal conductivity. When the semiconductor element is off, the semiconductor substrate 1 is cooled from a side of the lower surface, so that the plated electrode 4, the bonding material 5, and the lead frame 6 have lower temperatures than the protective film 3 and the molding resin 7. A temperature distribution (i.e., a difference in temperature between members) during operation of the semiconductor device as described above makes it difficult to equalize amounts of expansion and contraction of the members even when the members have close coefficients of linear expansion.

In the present embodiment, the boundary portion between the plated electrode 4 having a low peel strength and the protective film 3 is covered with the bonding material 5, and further a boundary between the molding resin 7 and the lead frame 6 (i.e., the end surface of the lead frame 6 covered with the molding resin 7) is not disposed above the boundary portion to reduce stress applied to the end of the plated electrode 4 due to the temperature distribution during operation of the semiconductor device. This prevents peeling of the plated electrode 4 and can contribute to improvement in reliability of the semiconductor device. In particular, the semiconductor device including the semiconductor substrate 1 formed of silicon carbide (SiC) has a wide operating temperature range and thus has a noticeable difference in amount of expansion and contraction between members, so that the above-mentioned effect is highly effective.

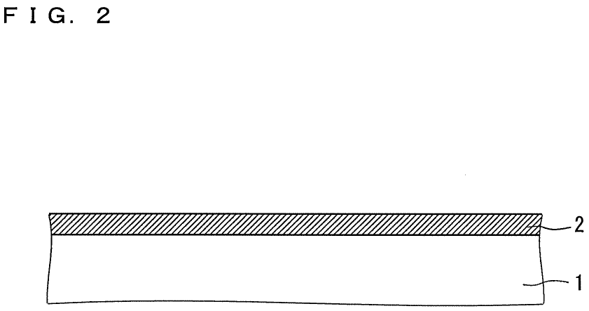

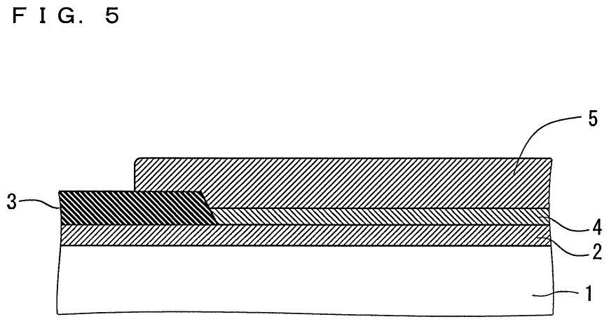

A method of manufacturing the semiconductor device according to Embodiment 1 will be described below with reference to process diagrams of FIGS. 2 to 7. From among FIGS. 2 to 7, FIGS. 2 to 4 illustrate a wafer process, and FIGS. 5 to 7 illustrate an assembly process. FIGS. 2 to 7 illustrate a portion near a position where the semiconductor substrate 1 and the lead frame 6 are connected as with FIG. 1. Processes relating to the portion will be described below, and description on the other processes (e.g., a dicing process, a die bond process, and a wire bond process) will be omitted.

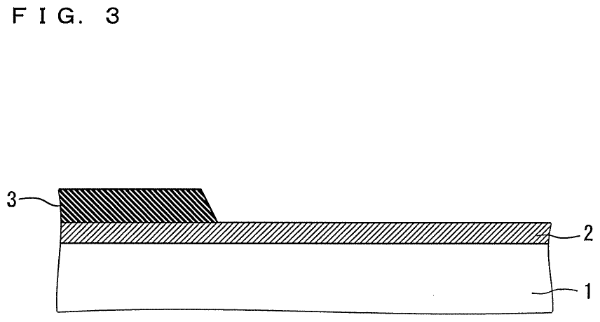

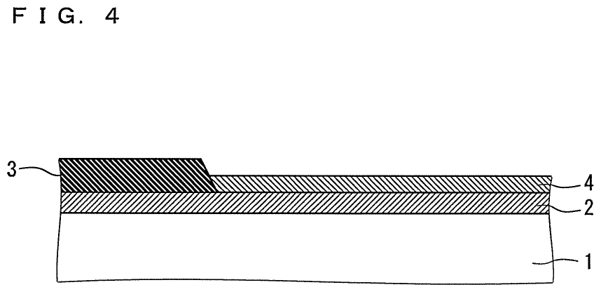

First, the semiconductor substrate 1 having the semiconductor element formed thereon is prepared, and the surface electrode 2 is formed on the surface of the semiconductor substrate 1 as illustrated in FIG. 2. Next, the protective film 3 is formed on the surface electrode 2, and the opening from which the portion of the surface electrode 2 is exposed is formed in the protective film 3 as illustrated in FIG. 3. A surface of the portion of the surface electrode 2 exposed from the opening of the protective film 3 is then plated to form the plated electrode 4 as illustrated in FIG. 4.

The bonding material 5 containing silver is then applied to the plated electrode 4 and a portion of the protective film 3 at the edge of the opening as illustrated in FIG. 5. The bonding material 5 can be applied by printing a nanosilver paste as the bonding material 5 onto the protective film 3 and the plated electrode 4, for example.

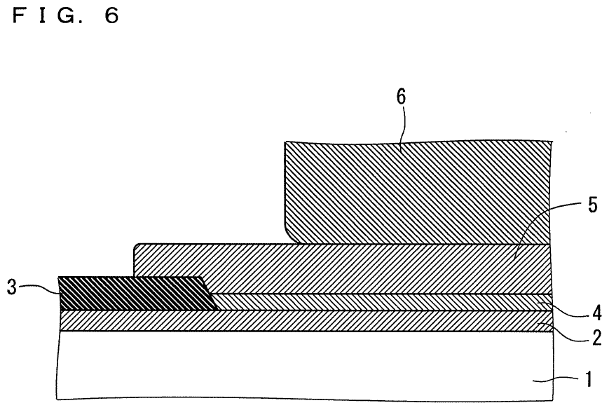

The bonding material 5 is heated with the lead frame 6 mounted thereon to connect the lead frame 6 and the plated electrode 4 via the bonding material 5 as illustrated in FIG. 6. As described above, when the nanosilver paste is used as the bonding material 5, it is preferable to pressurelessly sinter silver of the bonding material 5. In a state after sintering of silver of the bonding material 5, the above-mentioned relationships b>a and c>a preferably hold.

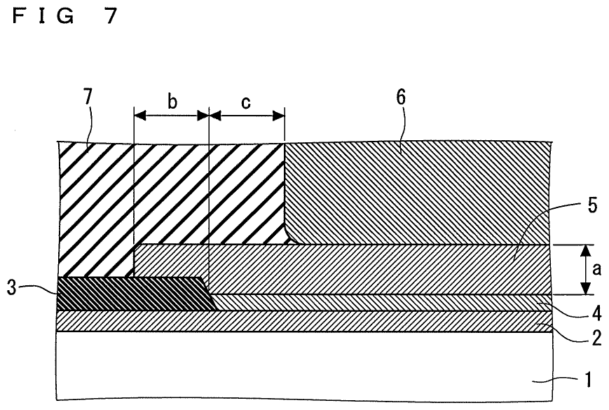

The semiconductor substrate 1, the surface electrode 2, the protective film 3, the plated electrode 4, and the lead frame 6 are finally sealed using the molding resin 7 as illustrated in FIG. 7 to obtain a configuration of the semiconductor device illustrated in FIG. 1.

### Embodiment 2

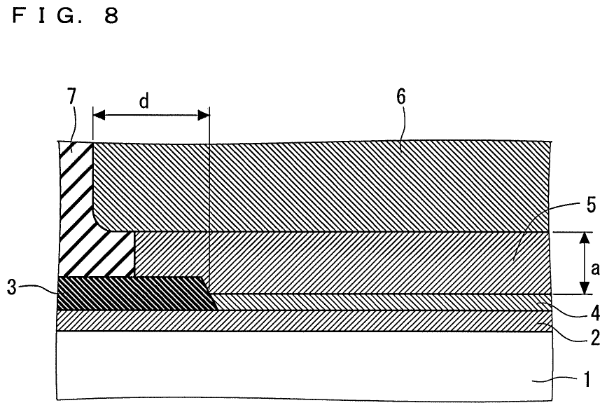

FIG. 8 is a cross-sectional view illustrating a configuration of a main portion of a semiconductor device according to Embodiment 2. In FIG. 8, the same or corresponding elements as or to those described in Embodiment 1 (FIG. 1) bear the same reference signs as those of the same or corresponding elements. Detailed description thereof is thus herein omitted, and a difference from Embodiment 1 will be described.

In Embodiment 2, the end surface of the lead frame 6 covered with the molding resin 7 is located outside the plated electrode 4. The other configuration is similar to that in Embodiment 1.

Also in the configuration illustrated in FIG. 8, the end surface of the lead frame 6 covered with the molding resin 7 is at the position offset from the position above the end of the plated electrode 4 (i.e., the boundary portion between the plated electrode 4 and the protective film 3), so that application of stress generated in the boundary portion between the lead frame 6 and the molding resin 7 to the end of the plated electrode 4 having a low peel strength is suppressed to suppress peeling of the plated electrode 4.

The amount of offset of the position of the end surface of the lead frame 6 covered with the molding resin 7 from the position of the end of the plated electrode 4 is preferably greater than the thickness of the portion of the bonding material 5 between the lead frame 6 and the plated electrode 4. That is to say, as illustrated in FIG. 8, a relationship d>a preferably holds, where d is the amount of offset of the position of the end surface of the lead frame 6 covered with the molding resin 7 from the position of the end of the plated electrode 4.

### Embodiment 3

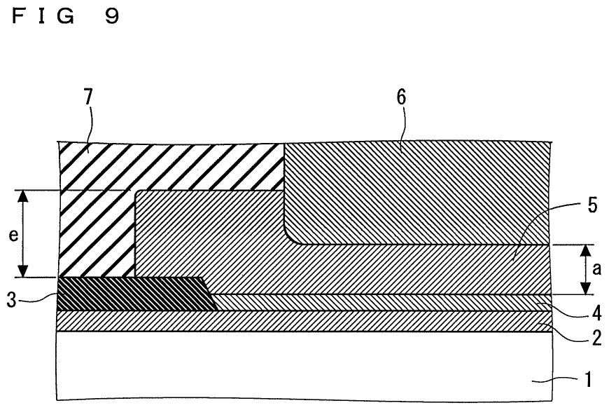

FIG. 9 is a cross-sectional view illustrating a configuration of a main portion of a semiconductor device according to Embodiment 3. Also in FIG. 9, the same or corresponding elements as or to those described in Embodiment 1 (FIG. 1) bear the same reference signs as those of the same or corresponding elements. Detailed description thereof is thus herein omitted, and a difference from Embodiment 1 will be described.

In Embodiment 3, a thickness of a portion of the bonding material 5 above the boundary portion between the plated electrode 4 and the protective film 3 is greater than the thickness of the portion of the bonding material 5 below the lead frame 6 (i.e., between the lead frame 6 and the plated electrode 4). That is to say, as illustrated in FIG. 9, a relationship e>a holds, where a is the thickness of the portion of the bonding material 5 between the lead frame 6 and the plated electrode 4, e is the thickness of the portion of the bonding material 5 above the boundary portion between the plated electrode 4 and the protective film 3. A material covering the end of the plated electrode 4 having a low peeling strength immediately around the end of the plated electrode 4 is thereby equalized, and a difference in amount of expansion and contraction due to the temperature distribution during operation of the semiconductor device can be reduced to suppress peeling of the plated electrode 4.

The bonding material 5 is only required to be applied by dispensing (i.e., applying using a dispenser) to partially control the thickness of the bonding material 5. By applying the bonding material 5 by printing, the bonding material 5 can efficiently be applied to a wide range, but the applied bonding material 5 has a constant thickness.

### Embodiment 4

In the present embodiment, the semiconductor devices according to Embodiments 1 to 3 described above are applied to a power converter. While application of the semiconductor devices according to Embodiments 1 to 3 is not limited to a particular power converter, a case where the semiconductor devices according to Embodiments 1 to 3 are applied to a three-phase inverter will be described in Embodiment 4 below.

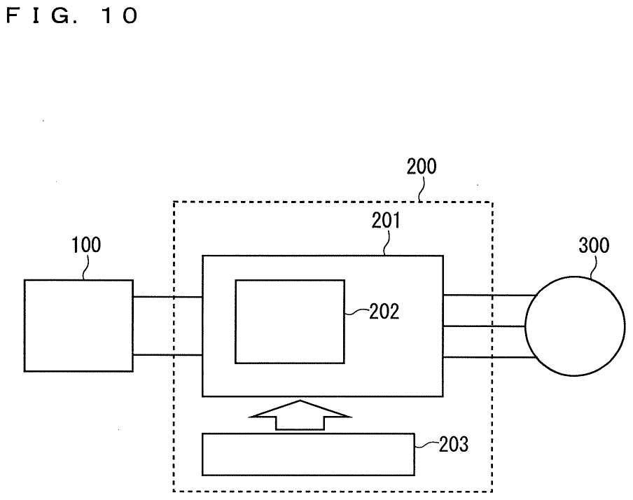

FIG. 10 is a block diagram showing a configuration of a power conversion system to which the power converter according to the present embodiment has been applied.

The power conversion system shown in FIG. 10 includes a power supply 100, a power converter 200, and a load 300. The power supply 100 is a DC power supply and supplies DC power to the power converter 200. The power supply 100 can be formed by various power supplies, can be formed by a DC system, a solar cell, and a storage battery, and may be formed by a rectifier circuit and an AC/DC converter connected to an AC system, for example. The power supply 100 may be formed by a DC/DC converter to convert DC power output from the DC system into predetermined power.

The power converter 200 is a three-phase inverter connected between the power supply 100 and the load 300, converts the DC power supplied from the power supply 100 into AC power, and supplies the AC power to the load 300. As shown in FIG. 10, the power converter 200 includes a main conversion circuit 201 to convert the DC power into the AC power for output and a control circuit 203 to output, to the main conversion circuit 201, a control signal to control the main conversion circuit 201.

The load 300 is a three-phase motor driven by the AC power supplied from the power converter 200. The load 300 is not limited to that for a particular application, is a motor mounted on various types of electrical equipment, and is used as a motor for hybrid vehicles, electric vehicles, railroad vehicles, elevators, or air-conditioning equipment, for example.

The power converter 200 will be described in detail below. The main conversion circuit 201 includes switching elements and freewheeling diodes (not shown), converts the DC power supplied from the power supply 100 into the AC power, and supplies the AC power to the load 300 through switching of the switching elements. While the main conversion circuit 201 can have various specific circuit configurations, the main conversion circuit 201 according to the present embodiment is a two-level three-phase full-bridge circuit and can include six switching elements and six freewheeling diodes connected in anti-parallel with the respective switching elements. Each of the switching elements and the freewheeling diodes of the main conversion circuit 201 is formed by a semiconductor module 202 corresponding to any one of Embodiments 1 to 3 described above. Every two switching elements out of the six switching elements are connected in series with each other to form pairs of upper and lower arms, and the pairs of upper and lower arms form respective phases (a U phase, a V phase, and a W phase) of the full-bridge circuit. Output terminals of the respective pairs of upper and lower arms, that is, three output terminals of the main conversion circuit 201 are connected to the load 300.

While the main conversion circuit 201 includes a drive circuit (not shown) to drive each of the switching elements, the drive circuit may be incorporated in the semiconductor module 202 or may be included separately from the semiconductor module 202. The drive circuit generates a drive signal to drive each of the switching elements of the main conversion circuit 201 and supplies the drive signal to a control electrode of each of the switching elements of the main conversion circuit 201. Specifically, in accordance with the control signal from the control circuit 203 described below, a drive signal to switch the switching element to an on state and a drive signal to switch the switching element to an off state are output to the control electrode of each of the switching elements. The drive signal is a voltage signal (an on signal) equal to or greater than a threshold voltage of the switching element when the switching element is maintained in the on state and is a voltage signal (an off signal) equal to or smaller than the threshold voltage of the switching element when the switching element is maintained in the off state.

The control circuit 203 controls the switching elements of the main conversion circuit 201 so that desired power is supplied to the load 300. Specifically, time (on time) during which each of the switching elements of the main conversion circuit 201 is to be in the on state is calculated based on power to be supplied to the load 300. For example, the main conversion circuit 201 can be controlled through PWM control to modulate the on time of each of the switching elements in accordance with a voltage to be output. A control command (the control signal) is output to the drive circuit of the main conversion circuit 201 so that the on signal is output to a switching element to be in the on state, and the off signal is output to a switching element to be in the off state at each time point. The drive circuit outputs, as the drive signal, the on signal or the off signal to the control electrode of each of the switching elements in accordance with the control signal.

In the power converter according to the present embodiment, the semiconductor modules according to Embodiments 1 to 3 are applied as the switching elements and the freewheeling diodes of the main conversion circuit 201 to achieve improvement in reliability.

While an example in which the semiconductor devices according to Embodiments 1 to 3 are applied to the two-level three-phase inverter has been described in the present embodiment, application of the semiconductor devices according to Embodiments 1 to 3 is not limited to this application, and the semiconductor devices according to Embodiments 1 to 3 are applicable to various power converters. While a two-level power converter has been described in the present embodiment, the power converter may be a three-level or multi-level power converter, and the semiconductor devices according to Embodiments 1 to 3 may be applied to a single-phase inverter when power is supplied to a single-phase load. The semiconductor devices according to Embodiments 1 to 3 are applicable to a DC/DC converter and an AC/DC converter when power is supplied to a DC load and the like.

The power converter to which the semiconductor devices according to Embodiments 1 to 3 are applied is not limited to that in the above-mentioned case where the load is the motor and can be used as a power supply device of an electrical discharge machine, a laser machine, an induction cooker, or a noncontact power supply system, for example, and can further be used as a power conditioner of a photovoltaic generation system, a storage system, and the like.

Embodiments can freely be combined with each other and can be modified or omitted as appropriate.

The foregoing description is in all aspects illustrative, and it is understood that numerous unillustrated modifications can be devised.

### EXPLANATION OF REFERENCE SIGNS

1 semiconductor substrate, 2 surface electrode, 3 protective film, 4 plated electrode, 5 bonding material, 6 lead frame, 7 molding resin, 100 power supply, 200 power converter, 201 main conversion circuit, 202 semiconductor module, 203 control circuit, 300 load.

1. A semiconductor device comprising:
a semiconductor substrate having a semiconductor element formed thereon;
a surface electrode formed on a surface of the semiconductor substrate;
a protective film formed on the surface electrode and having an opening from which a portion of the surface electrode is exposed;
a plated electrode formed on the portion of the surface electrode exposed from the opening of the protective film;
a lead frame connected to the plated electrode via a bonding material;
a molding resin to seal the semiconductor substrate, the surface electrode, the protective film, the plated electrode, and the lead frame, wherein
the molding resin is in contact with the bonding material, the protective film, and the lead frame,
the bonding material covers a portion of the protective film at an edge of the opening, and
a width of the portion of the protective film at the edge of the opening covered with the bonding material is greater than a thickness of a portion of the bonding material between the lead frame and the plated electrode.

2. The semiconductor device according to claim 1, wherein
a position of an end surface of the lead frame covered with the molding resin is offset from a position above an end of the plated electrode.

3. The semiconductor device according to claim 2, wherein
the amount of offset of the position of the end surface of the lead frame covered with the molding resin from a position of the end of the plated electrode is greater than the thickness of the portion of the bonding material between the lead frame and the plated electrode.

4. The semiconductor device according to claim 3, wherein
the end surface of the lead frame covered with the molding resin is located above the plated electrode.

5. The semiconductor device according to claim 3, wherein
the end surface of the lead frame covered with the molding resin is located outside the plated electrode.

6. The semiconductor device according to claim 1, wherein
a thickness of a portion of the bonding material above a boundary portion between the plated electrode and the protective film is greater than the thickness of the portion of the bonding material between the lead frame and the plated electrode.

7. The semiconductor device according to claim 1, wherein
the protective film is formed of polyimide.

8. The semiconductor device according to claim 1, wherein
the bonding material is a sintered body of silver.

9. The semiconductor device according to claim 1, wherein
the semiconductor substrate is formed of silicon carbide.

10. A power converter comprising:
a main conversion circuit to convert input power for output, the main conversion circuit including the semiconductor device according to claim 1; and
a control circuit to output, to the main conversion circuit, a control signal to control the main conversion circuit.

11. A method of manufacturing a semiconductor device, the method comprising:
forming a surface electrode on a surface of a semiconductor substrate having a semiconductor element formed thereon;
forming a protective film on the surface electrode and forming, in the protective film, an opening from which a portion of the surface electrode is exposed;
plating a surface of the portion of the surface electrode exposed from the opening of the protective film to form a plated electrode;
applying a bonding material containing silver on the plated electrode and a portion of the protective film at an edge of the opening;
mounting a lead frame on the bonding material and pressurelessly sintering silver of the bonding material to connect the lead frame and the plated electrode via the bonding material; and
sealing the semiconductor substrate, the surface electrode, the protective film, the plated electrode, and the lead frame using a molding resin.

12. The method of manufacturing the semiconductor device according to claim 11, wherein
after sintering of silver of the bonding material, a width of a portion of the protective film at the edge of the opening covered with the bonding material is greater than a thickness of a portion of the bonding material between the lead frame and the plated electrode.

13. The method of manufacturing the semiconductor device according to claim 11, wherein
after sintering of silver of the bonding material, a position of an end surface of the lead frame covered with the molding resin is offset from a position above an end of the plated electrode.

14. The method of manufacturing the semiconductor device according to claim 13, wherein
after sintering of silver of the bonding material, the amount of offset of the position of the end surface of the lead frame covered with the molding resin from a position of the end of the plated electrode is greater than a thickness of a portion of the bonding material between the lead frame and the plated electrode.

15. The method of manufacturing the semiconductor device according to claim 14, wherein
after sintering of silver of the bonding material, the end surface of the lead frame covered with the molding resin is located above the plated electrode.

16. The method of manufacturing the semiconductor device according to claim 14, wherein
after sintering of silver of the bonding material, the end surface of the lead frame covered with the molding resin is located outside the plated electrode.

17. The method of manufacturing the semiconductor device according to claim 11, wherein
after sintering of silver of the bonding material, a thickness of a portion of the bonding material above a boundary portion between the plated electrode and the protective film is greater than a thickness of a portion of the bonding material between the lead frame and the plated electrode.

18. The method of manufacturing the semiconductor device according to claim 11, wherein
the bonding material is applied by printing a nanosilver paste as the bonding material.

19. The method of manufacturing the semiconductor device according to claim 11, wherein
the bonding material is applied by dispensing a nanosilver paste as the bonding material.

20. The method of manufacturing the semiconductor device according to claim 11, wherein
the protective film is formed of polyimide.

21. The method of manufacturing the semiconductor device according to claim 11, wherein
the semiconductor substrate is formed of silicon carbide.
